(19) United States
(12) Patent Application Publication
(10) Pub. No.: US 2013/0337593 A1
(43) Pub. Date: Dec. 19, 2013

(54) METHOD FOR PRODUCING A PLURALITY OF SEMICONDUCTOR COMPONENTS

(71) Applicants: Hans-Christoph Gallmeier, Regensburg (DE); Günter Spath, Regensburg (DE); Herbert Brunner, Sinzing (DE)

(72) Inventors: Hans-Christoph Gallmeier, Regensburg (DE); Günter Spath, Regensburg (DE); Herbert Brunner, Sinzing (DE)

(73) Assignee: OSRAM OPTO SEMICONDUCTORS GmbH, Regensburg (DE)

(21) Appl. No.: 13/977,407

(22) PCT Filed: Dec. 15, 2011
(86) PCT No.: PCT/EP2011/072944

§ 371 Date: Sep. 4, 2013

(30) Foreign Application Priority Data
Dec. 30, 2010 (DE) 10 2010 056 571.7
Mar. 9, 2011 (DE) 10 2011 013 369.0

(51) Int. Cl. H01L 33/50

(52) U.S. Cl. CPC H01L 33/50
USPC 438/27

(57) ABSTRACT

A method for producing a plurality of radiation-emitting semiconductor components (10) is specified, said components each comprising at least one semiconductor chip (1) and a converter lamina (2). For this purpose, this method involves providing a plurality of semiconductor chips (1) in the wafer assembly (10a), said semiconductor chips each being suitable for emitting a primary radiation. Moreover, a plurality of converter laminae (2) are provided on a common carrier (2a), said converter laminae each being suitable for converting the primary radiation into a secondary radiation, wherein a converter lamina (2) is in each case mounted on one semiconductor chip (1) or onto a plurality of semiconductor chips (1) by means of an automated method.

The invention relates to a method for producing a plurality of semiconductor components comprising a semiconductor chip and a converter lamina.

In semiconductor components having a semiconductor chip and a converter lamina, the semiconductor chip emits a primary radiation during operation, wherein the converter lamina converts at least part of the primary radiation into a secondary radiation having a different wavelength. The resulting radiation arises from the superimposition of the primary radiation transmitted by the converter laminae and the secondary radiation generated. It is thus possible, for example, to produce semiconductor components which emit white light.

During the production of such components, the converter lamina is applied directly to the semiconductor chip usually by means of a screen printing method. However, a fluctuation of the color locus of the radiation (also referred to as chromaticity coordinate) emitted by the component can disadvantageously occur in this case. On account of the converter lamina being directly applied on the semiconductor chip, it is furthermore disadvantageous that defective converter laminae are applied to functioning semiconductor chips, and vice versa, and this can disadvantageously result in partly superfluous wear of the component parts of the components.

In the case where the converter lamina is directly applied on the semiconductor chip, it is disadvantageously not possible to assign a converter lamina to a semiconductor chip in a targeted manner depending on its converting property, in order thus to obtain a component having desired emission properties.

It is an object of the present application to specify a method wherein a converter lamina can be combined with a semiconductor chip in a targeted manner, wear of the component parts of the components simultaneously being reduced.

These objects are achieved, inter alia, by means of a production method comprising the features of claim 1. The dependent claims relate to advantageous developments of the production method.

In a development, the method for producing a plurality of radiation-emitting semiconductor components each having at least one semiconductor chip and a converter lamina comprises the following method steps:

a) providing a plurality of semiconductor chips in the wafer assembly, said semiconductor chips each being suitable for emitting a primary radiation,

b) providing a plurality of converter laminae on a common carrier, said converter laminae each being suitable for converting the primary radiation into a secondary radiation, and

c) mounting a converter lamina in each case on one semiconductor chip or onto a plurality of semiconductor chips by means of an automated method.

In this context, a converter lamina can in each case be mounted onto exactly one semiconductor chip. Alternatively, a common converter lamina can be disposed downstream of a plurality of semiconductor chips.

The converter laminae are thus separately produced laminae. A separately produced lamina should be understood to be, in particular, a lamina which is produced separately from the remaining constituent parts of the component. Accordingly, the lamina can be produced temporally before, in parallel with or after the production of the rest of the component. In the present case, the term “lamina” also encompasses layers which are flexible in a film-like manner and which can be produced separately and arranged onto the chip.

The conversion lamina is, in particular, a lamina in which part of the primary radiation emitted by the semiconductor chip is converted into a radiation having a different wavelength. The converter lamina can comprise a radiation-transmissive matrix material and a phosphor introduced in the matrix material. In this case, the matrix material determines the mechanical properties of the converter lamina. A radiation-stable and transparent material, in particular, is appropriate as matrix material. The matrix material is, for example, a thermoplastic or thermosetting plastic, for example silicone, or a ceramic. The refractive index of the matrix material is usually chosen in such a way that no undesirable scattering effects arise after the converter lamina has been applied on the semiconductor chip.

Phosphors introduced or embedded in the matrix material are described for example in the document WO 98/12757 A1, the disclosure content of which in this respect is incorporated by reference here.

The semiconductor chips each have an active layer, which preferably contains a pn junction, a double heterostructure, a single quantum well (SQW) structure or a multiquantum well (MQW) structure for generating radiation. In this case, the designation quantum well structure does not exhibit any significance with regard to the dimensionality of the quantization. It encompasses, inter alia, quantum wells, quantum wires and quantum dots and any combination of these structures.

The layers of the semiconductor chips each preferably comprise a III/V semiconductor. The semiconductor chips are in this case produced in the wafer assembly. A wafer assembly is, in particular, any arrangement which has a multiplicity of unpackaged semiconductor chips. This can be for example a semiconductor wafer, in particular a semiconductor wafer which has not been sawn, which has a multiplicity of individual semiconductor chips. The wafer assembly can likewise be a carrier on which a multiplicity of unpackaged, but already singulated semiconductor chips are applied, in order to enable further processing thereof.

The converter laminae can be applied to the wafer assembly individually or jointly in one piece, the wafer assembly subsequently being singulated. In this case, the semiconductor chips and possibly the converter laminae can be jointly singulated.

By means of the decoupling of the production of the converter laminae and of the semiconductor chips, it is possible to obtain, in particular, a production method wherein the color locus control of the radiation of the end product can be supervised better. Moreover, the wear of defective component parts is reduced, such as converter laminae or semiconductor chips, for example, since, prior to a combination of the converter laminae with the respective semiconductor chip, these can be tested and possibly removed by sorting.

A component produced in this way has the advantage, in particular, of near-chip conversion, wherein components which emit radiation in the white spectral range with narrow color locus distribution can be obtained. A maximum radiation efficiency of the component can be obtained on account of a targeted combination of the semiconductor chips with the converter laminae. Moreover, the production method is distinguished by low conversion costs and reduced problems in making contact with the semiconductor chip, for example making contact by means of a bonding wire. The decoupling of the methods for producing the converter laminae and the semiconductor chips furthermore has the advantage of an increased flexibility on account of the targeted combinations of converter lamina with respect to semiconductor chip.

The converter laminae can be embodied in a planar fashion or can have a three-dimensional structuring. The converter lamina can thus be configured as a flat lamina, wherein an exit surface of the lamina is fashioned as flat in this case. Alternatively, the exit surface of the lamina for desired coupling-out of light can have a three-dimensional structure, for example a lens-shaped structure, a curved structure or a roughened structure.

The converter laminae can contain ceramic or silicone, for example.

A plurality of converter laminae are produced simultaneously.

In a development, for mounting the converter laminae on the semiconductor chips, a conventional pick-and-place method is used, the principle of which is well known in semiconductor component mounting technology, in particular in chip mounting technology, and will therefore not be discussed in any greater detail at this juncture.

In a development, after method step b) and before method step c), the following method steps are carried out:

b1) measuring the degree of conversion of radiation of each converter lamina,

b2) sorting the converter laminae into a plurality of lamina groups depending on the degree of conversion of radiation,

b3) providing a plurality of semiconductor chip groups, wherein each group contains only semiconductor chips which emit a specific primary radiation,

b4) assigning a converter lamina group to a semiconductor chip group, such that each combination of converter lamina and semiconductor chip generates radiation that lies within a predetermined color locus range.

Such a method is distinguished, in particular, by the fact that the color control of the radiation of the end products can be supervised better. In particular, as a result of assigning a converter lamina group in which all laminae have the same degree of conversion or a degree of conversion within the same degree of conversion range to a semiconductor chip group in which all semiconductor chips have the same primary radiation or a primary radiation within the same emission range, groups of semiconductor components which have a very low color locus variation within the group can be produced in a comparatively simple manner.

In a development, the radiation of each combination of lamina group with semiconductor chip group lies within a common color locus range, in particular in the white color locus range.

In a development, the converter laminae are in each case fixed on the respective semiconductor chip by means of a clear silicone layer. The silicone layer is arranged on the semiconductor chips in particular by means of a jet process. In this case, the silicone layer is preferably applied prior to the mounting of the converter laminae on the semiconductor chips.

Alternatively, the converter laminae can in each case be applied by means of a layer composed of a material which has thermal, optical and adhesive properties that are the same as or similar to those of silicone.

In a development, the silicone layer is formed and applied as a drop on each semiconductor chip. In this case, each drop is preferably formed as a drop having a size of 5 nl to 20 nl inclusive. In this case, the size and extent of the drops are monitored in an automated manner, such that the sizes of the drops advantageously do not deviate, or do not deviate significantly, from the predetermined range. In this case, the silicone layer is applied to the semiconductor chips periodically. In particular, exactly one silicone drop is applied to each semiconductor chip.

Alternatively, the silicone layer or the layer composed of material having properties at least similar to those of silicone can be applied on each semiconductor chip by means of a jet process, a stamp process or a printing process. Moreover, there is the possibility, prior to the converter laminae being applied on the semiconductor chips, of arranging the silicone layer or the layer composed of material having properties at least similar to those of silicone on a side of the converter laminae, by which side the converter laminae are subsequently applied directly on the semiconductor chips.

In a development, prior to mounting the converter laminae on the semiconductor chips, the method involves determining whether the silicone layer is applied on each semiconductor chip. If it is ascertained in this case that no silicone layer is applied on a chip, no converter lamina is applied to said chip in the subsequent processing method. The determination of whether the silicone layer is applied on each semiconductor chip is made for example by means of a camera optical unit with polarization filters. What can thus be achieved is that no converter lamina is applied on a semiconductor chip which has no silicone.

In a development, the converter laminae are detached from the common carrier in each case by means of a vacuum process, in order subsequently to be able to be mounted on the semiconductor chips. It is thus possible to obtain a technique of picking up the converter laminae without needles, which is relevant in particular to converter laminae embodied as flexible silicone layers. Possible damage on account of the needles conventionally used can thus be avoided.

For the purpose of detaching the converter laminae from the common carrier, use is made of an adhesive layer arranged between the common carrier and the converter laminae, wherein, for the purpose of detaching the converter laminae, adhesive properties of the adhesive layer are reduced or eliminated by means of a heating process. For heating purposes, use is made of a so-called heating stamp. The latter is guided below the common carrier, such that the adhesive layer expands and loses its adhesive properties. The converter laminae can subsequently be detached from the common carrier without any problems by means of the vacuum process.

In a development, prior to mounting the converter laminae on the semiconductor chips, positions and orientations of the semiconductor chips in the wafer assembly are determined. The positions determined are registered in a so-called substrate map. The positions are determined for example on the basis of markings in the assembly, for example at the corner points of the assembly. With regard to the orientation of the semiconductor chips, what is of significance, in particular, is at what location in each semiconductor chip an upper contact area is formed. The contact areas are often arranged here in each case in a corner region of the semiconductor chips. These data, too, are determined and recorded.

If a position in the assembly has no semiconductor chip, this position is registered in the substrate map, such that no further processing takes place at this position.

In a development, prior to mounting the converter laminae on the semiconductor chips, positions and orientations of the converter laminae on the common carrier are determined. This determination is made for example by means of markings or on account of cutouts of the converter laminae in provided regions of the corner contact areas of the semiconductor chips.

In a development, in the course of mounting the converter laminae on the semiconductor chips, the orientation of the respective converter lamina is adapted to the respective orientation of the semiconductor chip. In particular, the converter laminae are in each case arranged on the semiconductor chips such that the cutout of the converter laminae is arranged above the corner contact of the semiconductor chip.

The orientation of the converter laminae is determined, for example, by means of a so-called uplooking camera (ULC), which is well known to the person skilled in the art and will therefore not be discussed in any greater detail at this juncture. In the course of mounting the converter laminae on the semiconductor chips, in particular a rotation of the converter laminae or semiconductor chips is taken into consideration, such that the converter laminae are applied with a similar form on the semiconductor chips.

After the individual components have been completed, the emission characteristics of said components can be checked by means of camera optical units. If the converter lamina is applied on the semiconductor chip in a rotated or displaced manner, then these components can be marked as “poor” in the substrate map, such that these components can subsequently be removed by sorting.

The wafer assembly with chips arranged thereon can subsequently be singulated into individual components, for example by means of sawing, wherein, after singulation, a respective component preferably comprises a semiconductor chip with converter laminae arranged thereon.

In a development, the preferably singulated semiconductor components are in each case arranged in a housing body in an additional method step d). Depending on the desired use, the desired type of housing body can be selected. The housing bodies can subsequently be potted after the mounting of the semiconductor components.

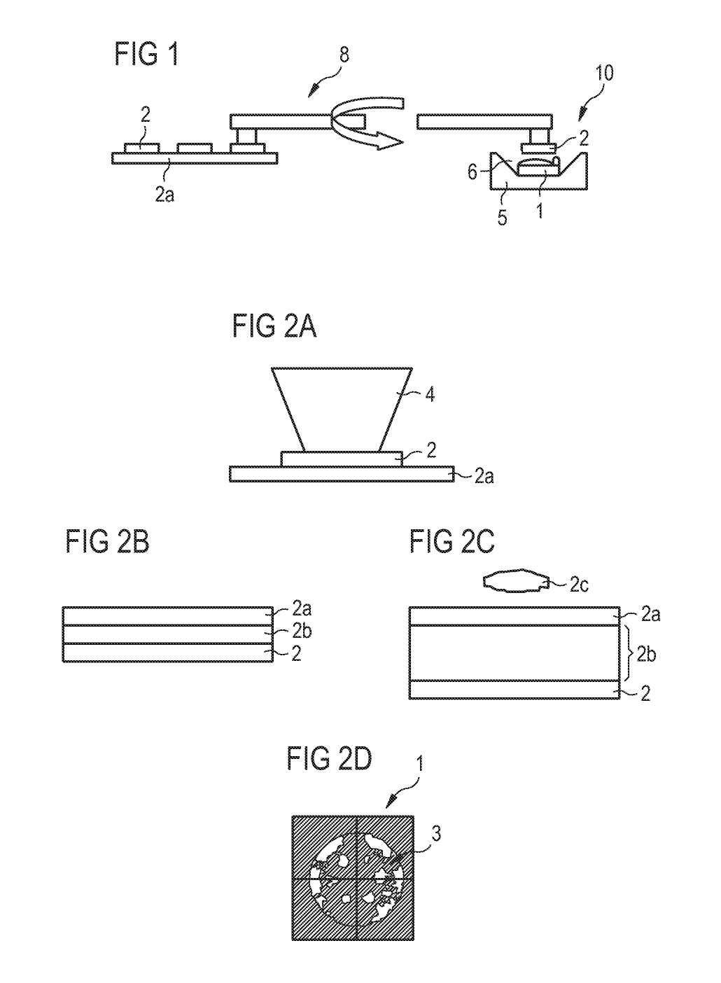

Further advantages and advantageous developments of the invention will become apparent from the exemplary embodiments described below in conjunction with FIGS. 1 to 3, in which:

FIG. 1 shows a schematic view of an exemplary embodiment of a mounting process according to the invention in the production method according to the invention,

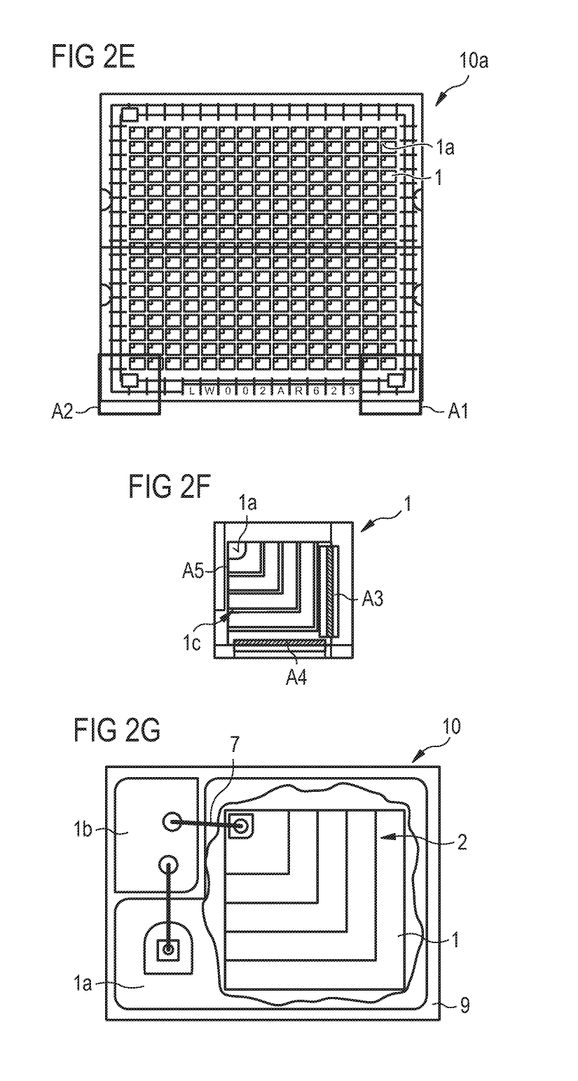

FIGS. 2A to 2G each show a view of a semiconductor chip or converter lamina in the production method according to the invention, and

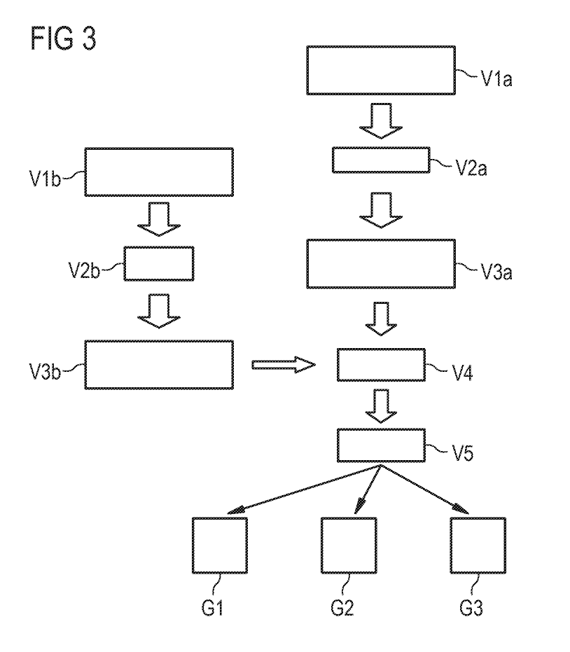

FIG. 3 shows a schematic flow chart in conjunction with a production method according to the invention.

In the figures, identical or identically acting constituent parts may in each case be provided with the same reference signs. The illustrated constituent parts and their size relationships among one another should not be regarded as true to scale, in principle. Rather, individual constituent parts, such as, for example, layers, structures, component parts and regions, may be illustrated with exaggerated thickness or size dimensions in order to enable better illustration and/or in order to afford a better understanding.

FIG. 1 illustrates a schematic view of a mounting process in the method for producing a semiconductor component comprising a semiconductor chip and a converter lamina. In order to produce such a component, a plurality of converter laminae 2 are provided on a common carrier 2a, as shown in the left-hand part of FIG. 1. In this case, the converter laminae 2 are arranged periodically, for example in a matrix-like manner, on the common carrier 2a. The converter laminae 2 are at distance from one another, such that the converter laminae 2 do not directly adjoin one another.

In addition, a plurality of semiconductor chips in a wafer assembly are provided, as shown as an excerpt in the right-hand part of FIG. 1. In this case, the semiconductor chips 1 are arranged in a housing 5, for example, wherein the housing has a cutout in which the semiconductor chip 1 is arranged. The cutout of the housing body 5 in this case contains air, for example.

The semiconductor chip is suitable for emitting a primary radiation. By way of example, the semiconductor chip 1 emits blue radiation. The converter laminae 2 are suitable for converting the primary radiation of the semiconductor chip/semiconductor chips 1 into a secondary radiation. By way of example, the converter laminae 2 are suitable for converting blue radiation into yellow radiation.

A converter lamina 2 is in each case detached from the common carrier 2a by means of an automated method 8, for example a pick-and-place method, and disposed downstream of the semiconductor chip 1 in the emission direction, as illustrated by the arrow in FIG. 1. In the present exemplary embodiment, the converter lamina 2 is arranged directly vertically on the semiconductor chip 1, such that radiation emitted by the semiconductor chip 1 passes at least partly through the converter lamina 2. The component 10 produced in this way thus emits mixed radiation comprising primary radiation and secondary radiation, the mixed radiation preferably lying in the white color locus range.

The semiconductor chips can alternatively be embodied in a wafer assembly as a multiplicity of unpackaged, but already singulate semiconductor chips. In this case, the converter laminae are respectively disposed directly downstream of the semiconductor chips by the converter laminae being applied to a radiation exit side of the semiconductor chips.

The individual method steps are explained in greater detail in connection with FIGS. 2A to 2F and 3.

FIG. 2A shows the process for detaching the converter lamina 2 from the common carrier 2a. The converter lamina 2 is fixed directly on the common carrier 2a. In order to detach the converter lamina 2 from the carrier 2a, a vacuum process is used, for example. For this purpose, for example a vacuum device 4 is used, for example a suction unit formed by means of a vacuum method. In this case, the vacuum device 4 is guided directly over the converter lamina 2, in particular is brought into direct contact with the converter laminae 2 on the opposite side relative to the common carrier 2a. The converter lamina 2 is sucked onto the vacuum device by means of a vacuum process, such that it adheres thereto, whereby the converter lamina 2 can be detached from the common carrier 2a. By means of the vacuum device 4, the converter lamina 2 can subsequently be disposed downstream of the semiconductor chip, as illustrated for example by the arrow in FIG. 1.

In this case, the common carrier 2a is embodied such that the converter lamina 2 is fixedly connected to the common carrier 2a, wherein this fixed connection can be reduced or eliminated by means of a heating process. A common carrier 2a embodied in this way is illustrated for example in FIGS. 2B and 2C.

As illustrated in FIG. 2B, an adhesive layer 2b is arranged between the common carrier 2a and the converter lamina 2. Such an adhesive layer is also known to the person skilled in the art by the term “thermal release adhesive” inter alia. The adhesive layer 2b has adhesive properties, such that the converter lamina is fixedly connected to the common carrier 2a. However, these adhesive properties of the adhesive layer can be reduced or eliminated by means of a heating process, as illustrated in FIG. 2C.

For this purpose, a heating device 2c, for example a heating stamp, is arranged on that side of the common carrier 2a which faces away from the converter lamina 2, such that said heating device 2c heats the common carrier 2a and the adhesive layer 2b. On account of this heating process, the adhesive properties of the adhesive layer 2b are advantageously reduced as the adhesive layer 2b is foamed or expands due to the heating process. On account of this foaming that results in the adhesive properties of the adhesive layer 2b being reduced or eliminated, the converter lamina 2 can be lifted off from the common carrier 2a without any problems by means of a vacuum device, as illustrated in FIG. 2A, for example, and then processed further. On account of this vacuum lift-off, damage such as can occur for example during a detachment process by means of a needle can advantageously be avoided.

FIG. 2D illustrates a semiconductor chip 1 in plan view, on which semiconductor chip a silicone layer, in particular a silicone drop 3, is applied. The silicone drop 3 is provided for fixing the converter lamina on the semiconductor chip. For this purpose, a silicone drop having a volume in a range of between 15 nl and 20 nl inclusive is applied dropwise to that side of the semiconductor chip 1 onto which the converter lamina is intended to be arranged. The converter lamina 2 is subsequently placed onto said silicone drop 3, the silicone being cured, thus giving rise to a fixed connection between the semiconductor chip 1 and the converter lamina.

The production method involves providing the components in the wafer assembly, as illustrated in FIG. 2E, for example. In this case, a respective silicone drop is applied to a semiconductor chip. After the silicone drops have been applied, by means of a camera optical unit and polarization filters, the wafer assembly is checked or it is determined whether a silicone drop is applied on each semiconductor chip. In this case, the camera optical unit can determine a reflection of the substrate in the silicone drop. If no reflection is determined, this semiconductor chip is marked in a so-called substrate map, such that this chip is not processed further. In particular, no converter lamina is applied to the marked semiconductor chips in the subsequent method. In this case, the checking and marking of the semiconductor chips are used in the automated method.

The checking of the semiconductor chips is illustrated in greater detail in FIG. 2E. FIG. 2E shows, in particular, a plan view of a wafer assembly 10a with unpackaged optoelectronic semiconductor chips 1. In this case, the layers of the semiconductor chips 1 are grown epitaxially onto the wafer 10a. In this case, the layers of the semiconductor chips 1 have an active layer. The active layer has, for example, a radiation-generating pn junction or a radiation-generating single or multiquantum well structure. The semiconductor chips 1 are arranged in a matrix-like manner on the wafer 10a. In this case, the semiconductor chips 1 are arranged adjacent to one another. In this case, the wafer assembly 10a has a chip grid having a plurality of said semiconductor chips 1. Contact areas are in each case applied on the semiconductor chips and serve for making electrical contact with the semiconductor chips.

In order, as explained in conjunction with FIG. 2B, to detect whether a silicone drop is applied on each semiconductor chip 1, the position and orientation of the semiconductor chips 1 in the wafer assembly are determined by means of markings. In conjunction with FIG. 2E, the markings A1, A2 lie at the corner points of the wafer assembly 10a. From these markings A1, A2, it is possible to determine the exact position and orientation of the semiconductor chips 1, which are registered in the substrate map. If it is ascertained at a position of the wafer assembly 10a, for example, that this position has no chip, then this position is registered in the substrate map with the aid of the markings A1, A2. On account of this registration no further processing takes place at this position.

In addition, the orientation of the semiconductor chips 1 in the wafer assembly is determined. This determination is illustrated in connection with FIG. 2F. FIG. 2F shows a plan view of a semiconductor chip 1 in the assembly. A contact area 1a and current distribution connections 1c are illustrated on the surface of the semiconductor chip 1. The semiconductor chips 1 are in each case scanned by means of a camera optical unit, wherein the contact area 1a is determined as marking A5. In addition, the side surfaces are determined by means of markings A3, A4. By means of these markings and by means of the contact area, the respective orientation of the semiconductor chip 1 in the wafer assembly can thus be determined and recorded in a so-called module map. The orientation of the semiconductor chips is necessary, in particular, in order to optimally arrange the converter laminae on the semiconductor chip 1 in a subsequent method step.

By means of such contact areas 1a and current distribution connections 1c on the surface of the semiconductor chips, electrical contact can be made with the semiconductor chips by means of a bonding wire, for example, after completion. Alternative contact-connections without the use of bonding wires, such as a planar contact-making technique, for example, can also be used. Such contact-making techniques are known to the person skilled in the art and will therefore not be discussed in any greater detail at this juncture.

Moreover, such a contact area 1a and current distribution connections 1c on the surface of the semiconductor chips are not absolutely necessary. The person skilled in the art knows, in particular, contact-making techniques in which a contact area on the top side is not necessary, such as, for example, a flip-chip contact-making technique, which will likewise not be explained in any greater detail at this juncture.

In addition to this, the position and the orientation of the converter laminae on the common carrier are determined. This determination takes place by means of a camera optical unit, wherein the orientation and positions of the converter laminae are likewise recorded in a so-called converter map. The converter laminae have a corner cutout, in which the contact area of the semiconductor chip is to be arranged. In this case, this cutout is to be arranged directly above the contact area of the semiconductor chip in a later method step.

FIG. 2G illustrates a plan view of a component 10 produced to completion. The component 10 has a carrier 9 on which the semiconductor chip 1 is arranged. The carrier 9 has a first conductor track 1a and a second conductor track 1b, which are arranged on that side of the carrier 9 onto which the chip is arranged. The semiconductor chip 1 is directly electrically and mechanically connected in particular to an electrical connection area on the conductor track 1a of the carrier 9. The semiconductor chip 1 is electrically conductively connected to the second conductor track 1b of the carrier 9 by the contact area by means of a bonding wire 7. The conductor tracks 1a, 1b of the carrier are arranged in a manner electrically insulated from one another, for example by means of a distance.

The conductor lamina is arranged on that side of the semiconductor chip 1 which faces away from the carrier 9. In this case, the converter lamina is oriented in such a way that the cutout of the converter lamina 2 lies in the region of the contact area of the semiconductor chip 1. Moreover, the converter lamina 2 is oriented in such a way that no rotation with respect to the semiconductor chip 2 is present, the converter lamina 2 being arranged centrally on the semiconductor chip 1.

A component produced in this way can be checked by means of a camera optical unit after the production process. If, in this case, the orientation of the converter lamina 2 with respect to the semiconductor chip is not optimal, then these semiconductor chips are marked as poor in the substrate map.

The component 10 as illustrated in FIG. 2G is still situated in the wafer assembly, wherein, after the production process, the wafer assembly can be singulated to form individual components by means of a sawing process, for example.

FIG. 3 illustrates a method sequence of an exemplary embodiment of the method according to the invention for producing a plurality of radiation-emitting semiconductor components. According to this method it is possible to produce semiconductor components which have a predetermined common color locus and lie within a common color locus range, preferably in the white color locus range. Semiconductor components whose radiation and color have a common color locus or color locus range are designated here as a semiconductor component group.

In method step V1b, a plurality of separately produced converter laminae are made available. These laminae are arranged, in particular, on a common carrier.

In method step V2b, the degree of conversion of radiation of each lamina is measured. By way of example, the laminae can be measured individually by means of a measuring apparatus in which a semiconductor chip having a known wavelength distribution is arranged.

In method step V3b, all the converter laminae are sorted into lamina groups depending on the measured degree of conversion, such that all laminae in a lamina group have a specific common degree of conversion or lie within a specific common degree of conversion range.

If, in this case, a very precise color locus is desired in the finished semiconductor components, the laminae are preferably sorted into lamina groups which are in each case characterized by a very narrow degree of conversion range. If the permissible tolerance in the color locus control is higher in the finished semiconductor components, the degree of conversion range can be chosen to be wider.

In method steps V1a to V1a, the same analogously applies to sorting the semiconductor chips into semiconductor chip groups. Method step V1a involves providing a plurality of semiconductor chips in the wafer assembly, and their emission wavelength of the primary radiation is determined in method step V2a. Depending on the determined emission wavelength of the primary radiation, the semiconductor chips are classified in groups, the group classification being noted in the module map.

In the subsequent method step V4, the converter lamina groups are respectively assigned to a semiconductor chip group, such that each combination of converter laminae and semiconductor chips generates radiation which lies within a predetermined color locus range, preferably within a common color locus range, particularly preferably within a white color locus range. On account of this sorting, it is possible to obtain a method for producing components wherein the color locus variation of the radiation of the end product can be supervised better.

In method step V5, the converter laminae from the chosen lamina group are in each case mounted on the semiconductor chips from the chosen semiconductor chip group by means of an automated method, preferably a pick-and-place method. The mounting is effected, for example, by means of the silicone drop, as explained in FIG. 2D. The converter laminae are detached from the common carrier, for example, by means of the method as explained in FIGS. 2A to 2C. The orientation of the semiconductor chips and the sorting of the semiconductor chips are effected, for example, by means of the marking processes in FIGS. 2E and 2F.

After the laminae of a lamina group have been mounted on the semiconductor chips of an assigned semiconductor chip group, a plurality of semiconductor components which all have radiation within a common color locus range have been produced. The semiconductor components of a lamina/semiconductor chip group in combination respectively belong to a semiconductor component group G1, G2 or G3.

If the permissible tolerance for color locus variation of the semiconductor components is high, the measurement of the degree of conversion of the laminae and/or of the primary radiation of the semiconductor chips and the assigning can be dispensed with. In this case, the laminae provided are mounted randomly onto semiconductor chips provided, by means of the automated method.

The invention is not restricted to the exemplary embodiments by the description on the basis of said exemplary embodiments, but rather encompasses any novel feature and also any combination of features, which in particular includes any combination of features in the patent claims, even if this feature or this combination itself is not explicitly specified in the patent claims or exemplary embodiments.

This patent application claims the priorities of German patent applications 10 2010 056 571.7 and 10 2011 013 369.0, the disclosure content of which is hereby incorporated by reference.

1. A method for producing a plurality of radiation-emitting semiconductor components each having at least one semiconductor chip and a converter lamina, the method comprising the following steps:
a) providing a plurality of semiconductor chips in the wafer assembly, said semiconductor chips each being suitable for emitting a primary radiation;
b) providing a plurality of converter laminae on a common carrier, said converter laminae each being suitable for converting the primary radiation into a secondary radiation; and
c) mounting a converter lamina in each case on one semiconductor chip or onto a plurality of semiconductor chips by means of an automated method.

2. The method according to claim 1, wherein a pick-and-place method is used in accordance with step c).

3. The method according to claim 1, wherein, after step b) and before step c), the method further comprises the following steps:
b1) measuring the degree of conversion of radiation of each converter lamina;
b2) sorting the converter laminae into a plurality of lamina groups depending on the degree of conversion of radiation;
b3) providing a plurality of semiconductor chip groups, wherein each group contains only semiconductor chips which emit a specific primary radiation; and
b4) assigning a converter lamina group to a semiconductor chip group, such that each combination of converter lamina and semiconductor chip generates radiation that lies within a predetermined color locus range.

4. The method according to claim 3, wherein the radiation of each combination of lamina group with semiconductor chip group lies within a common color locus range.

5. The method according to claim 1, wherein the converter laminae are fixed on the semiconductor chips in each case by means of a silicone layer.

6. The method according to claim 5, wherein the silicon layer is formed as a drop on each semiconductor chip.

7. The method according to claim 6, wherein the silicone layer is formed as a drop having a size of 15 nl to 20 nl inclusive.

8. The method according to claim 5, wherein, prior to mounting the converter laminae on the semiconductor chips, the method further comprises determining whether the silicone layer is applied on each semiconductor chip.

9. The method according to claim 1, wherein the converter laminae are detached from the common carrier in each case by means of a vacuum process.

10. The method according to claim 9, wherein an adhesive layer is arranged between the common carrier and the converter laminae, and, for the purpose of detaching the converter laminae, adhesive properties of the adhesive layer are reduced or eliminated by means of a heating process.

11. The method according to claim 1, wherein, prior to mounting the converter laminae on the semiconductor chips, positions and orientations of the semiconductor chips in the wafer assembly are determined.

12. The method according to claim 1, wherein, prior to mounting the converter laminae on the semiconductor chips, positions and orientations of the converter laminae on the common carrier are determined.

13. The method according to claim 11, wherein, in the course of mounting the converter laminae on the semiconductor chips, the orientation of the respective converter lamina is adapted to the respective orientation of the semiconductor chip.

14. The method according to claim 1, wherein the semiconductor components are in each case arranged in a housing body in an additional step d).

15. The method according to claim 14, wherein the semiconductor components are in each case potted.

16. A method for producing a plurality of radiation-emitting semiconductor components each having at least one semiconductor chip and a converter lamina, the method comprising at least the following steps:
a) providing a plurality of semiconductor chips in the wafer assembly, said semiconductor chips each being suitable for emitting a primary radiation;
b) providing a plurality of converter laminae on a common carrier, said converter laminae each being suitable for converting the primary radiation into a secondary radiation; and
c) mounting a converter lamina in each case on one semiconductor chip or onto a plurality of semiconductor chips by means of an automated method,
wherein a pick-and-place method is used in accordance with step c),
wherein the semiconductor components are in each case arranged on a carrier comprising conductor tracks or in a housing body in an additional step d), said step d) being done before step c),
wherein the converter laminae are fixed on the semiconductor chips in each case by means of a silicone layer, and
wherein the silicone layer is formed as a drop having a size of 5 nl to 20 nl, inclusive.

17. The method according to claim 16, wherein the converter laminae comprise a transparent matrix material and a phosphor introduced in the matrix material, the matrix material determines the mechanical properties of the converter laminae, and
wherein the matrix material is a silicone or a ceramic.
